(19) United States
(12) Patent Application Publication
(10) Pub. No.: US 2016/0072258 A1
(43) Pub. Date: Mar. 10, 2016

(54) High Resolution Structured Light Source

(71) Applicant: Princeton Optronics Inc., Mercerville, NJ (US)

(72) Inventors: Jean-Francois Seurin, Princeton Junction, NJ (US); Chuni L. Ghosh, West Windsor, NJ (US); Tong Chen, Belle Mead, NJ (US); Laurence S. Watkins, Pennington, NJ (US)

(73) Assignee: PRINCETON OPTRONICS INC., Mercerville, NJ (US)

(21) Appl. No.: 14/848,791

(22) Filed: Sep. 9, 2015

Related U.S. Application Data
(60) Provisional application No. 62/048,351, filed on Sep. 10, 2014.

(51) Int. Cl. H01S 5/40; H01S 5/187; H01S 5/183; H01S 5/00; H04N 13/02; H04N 5/225

(52) U.S. Cl. CPC H01S 5/4025; H04N 13/0296; H04N 13/0203; H04N 5/2254; H04N 5/2256; H01S 5/183; H01S 5/005; H01S 5/187; H01S 5/18308

(57) ABSTRACT

A structured light source comprising VCSEL arrays is configured in many different ways to project a structured illumination pattern into a region for 3 dimensional imaging and gesture recognition applications. One aspect of the invention describes methods to construct densely and ultra-densely packed VCSEL arrays with to produce high resolution structured illumination pattern. VCSEL arrays configured in many different regular and non-regular arrays together with techniques for producing addressable structured light source are extremely suited for generating structured illumination patterns in a programmed manner to combine steady state and time-dependent detection and imaging for better accuracy. Structured illumination patterns can be generated in customized shapes by incorporating differently shaped current confining apertures in VCSEL devices. Surface mounting capability of densely and ultra-densely packed VCSEL arrays are compatible for constructing compact on-board 3-D imaging and gesture recognition systems.

### CROSS REFERENCE TO RELATED APPLICATION

This application claims priority from the United States Provisional Patent Application No. 62/048,351 filed on Sep. 10, 2014, by Seurin et al., content of that application is being incorporated by reference in its entirety.

### BACKGROUND OF THE INVENTION

1. Field of Invention

This invention relates to a structured light source and in particular, high resolution structured light source for generating high resolution passive and dynamically reconfigurable structured illumination patterns for applications that require three dimensional imaging including gesture recognition.

2. Background Art

Structured illumination is emerging as an important method for 3-D (three dimensional) imaging of objects in a scene in applications that vary from gesture recognition, video gaming, surveillance, Computer Aided Manufacturing (CAM), printing, etc., just to name a few. Structured illumination method for 3-D imaging is often used with other methods like time of flight and stereovision systems for better accuracy. In a typical 3-D imaging apparatus, for example one shown in the United States Patent Application Publication No. 2015/0130932 by Vrendenborg et al. published on May 14, 2015, a region is illuminated using a light source that generates a unique illumination pattern and a camera or a light sensor placed off axis from the illumination source detects and records multiple images of individual objects located in the illuminated area.

In one embodiment of the above mentioned prior art, a second light source including a structured light source is used to image an object while the first structured light source illuminates the object. A composite image may be generated by overlapping the recorded images to perform suitable analysis in relation to the projected structured illumination to estimate distance/depth information of the objects in the region. This basic methodology is adapted in many other 3-D imaging apparatus known in the art.

In general, structured illumination comprises two parts—a structured light source to generate a structured illumination pattern, and a projection apparatus which may include a single, or a combination of different optical elements. The projection element projects a scaled version of the structured illumination pattern generated by the light source on to an imaging region in physical space. In some prior art apparatuses a single light source is used to generate a structured illumination pattern with a simple opaque pattern mask, or a more complex mask, such as a diffractive optical element (DOE), a hologram, or a combination of these methods known in the art. Often times, the projection apparatus may include optical elements that also generate the structured illumination pattern. In all of these cases there is significant light loss associated with the use of a mask that reduces the brightness and resolution of the structured illumination pattern.

A single light source may be any kind of a semiconductor light source that are easily fabricated in an array, such as Light Emitting Diode (LED) or surface emitting LED, an edge-emitting or surface emitting laser. A preferred source in a state of the art imaging apparatus is a Vertical Cavity Surface Emitting Laser (VCSEL), and in particular, one or more arrays of VCSELs due to their small size, superior emission characteristics, ease of volume production as well as wafer level testing and integration with other optical components and electronic devices. VCSELs may be constructed to operate at many different wavelengths with generally round, but also differently shaped beams, having good collimation that preserve directionality over a relatively large distance as compared to other semiconductor light sources.

VCSELs also have excellent wavelength and temperature stability, low catastrophic failure rate and very high long-term reliability. VCSELs may be operated at high speed pulse rates with very short pulses and very fast pulse rise times resulting from gain switching and relaxation resonance properties, which are conducive to high speed time of flight measurement. Added advantage of the array source is that each device or a group of devices (sub-arrays or clusters) may be independently addressable providing extreme flexibility in reconfigurable patterns with relative ease.

In a recent International Patent Application Publication No. WO 2013/127974 A1 by Herschbach et al. published on Sep. 6, 2013, a structured light source is disclosed to generate a non-regular shaped unique structured illumination pattern by position coding each device in an addressable array. In a different United States Application Publication No. 2015/0092258 by Herschbeach et al., published on Apr. 2, 2015, a switchable diffuser is used in conjunction with a VCSEL array light source such that a region may be illuminated using a uniform illumination or a structured illumination pattern for 3-D imaging using a combination of different methods.

In some other prior art apparatus, one or more diffractive optical element (DOE) is used to generate a structured illumination pattern. For example, a structured light source disclosed in the International Patent Application Publication No. WO 2009/127974 by Becker et al., published on Dec. 23, 2009, uses a collimating DOE and a light structuring DOE to generate a structured illumination pattern. In yet another International Patent Application Publication No. WO 2005/036211 by Zalevsky et al., published on Apr. 21, 2005, structured illumination pattern using DOE and phase masks (filters) is disclosed. In a different approach, generation and projection of a structured illumination pattern comprising parallel lines using one or more DOE is disclosed in the International Patent Application Publication No. WO 2014/203110 by Zafrir, published on Dec. 24, 2014.

In another approach structured illumination patterns are generated and projected by translating, scanning or sweeping a VCSEL array source and the reflected light from an object is tracked synchronously with the translator or scanner device. For example, in the United States Patent Application Publication No. 2012/0307075 by Margalit et al. published on Dec. 6, 2012, tracking and synchronous image processing techniques is used for 3-D imaging. In another U.S. Pat. No. 5,325,386 issued to Jewell et al. on Jun. 28, 1994, a visual display system using scanning and sweeping method of a VCSEL array is disclosed.

There are limitations to different prior art apparatuses which affects the resolution of the structured illumination pattern and impacts the accuracy of depth information in 3-D measurement. For example, the smallest size of the typical state of the art LED or VCSEL device is 5 μm and the minimum spacing of devices in an array is about 15 μm, and more typically about 25 μm. Thus about 100,000 VCSEL devices may be accommodated in a 5×5 mm chip. Pattern definition and resolution of the structured illumination pattern which is directly related to the array pitch (distance between adjacent VCSEL devices in an array) may be compromised. In particular, image distortion due to diffraction and lens aberrations may be significant when the pattern is projected at a large distance from the source.

In one approach described in the United State Patent Application Publication No. 2013/0038881 published on Feb. 14, 2013, and No. 2014/0211215 published on Jul. 31, 2014, both by Pesach et al., a two-step projection system is disclosed to overcome the above mentioned limitations. A combination of DOE and refractive optical components are used to project a structured illumination pattern to a relatively large distance without causing significant image distortion.

It is further desirable to generate structured illumination pattern in different shapes and sizes. In one approach described in the International Patent Application Publication No. WO 2014/083485 by Moench et al., published on Jun. 5, 2014, emission from several laser arrays, each one comprising an irregular distribution of emission areas are superimposed to project a desired pattern on a plane. In another approach disclosed in the U.S. Pat. No. 9,048,633 issued to Grönenborn on Jun. 2, 2015, a desired intensity distribution on a working plane is generated by VCSEL devices having differently shaped apertures to project alternate beam shapes. However, the method does not describe generation of a structured illumination pattern.

While the prior art structured light sources comprising VCSEL arrays are adequate for current 3-D imaging applications. Current state of the art VCSEL arrays do not provide sufficient resolution and brightness because the VCSELs used in these prior art sources are typically basic 2-mirror self-emitting devices that only operates with very low power typically <5 mW in low order or single transverse mode. Operating the VCSEL at higher power results in multimode operation so that although the laser beam power is increased the brightness of the beam is not increased. Furthermore, efficiency of prior art VCSEL arrays is low and require additional current spreading or resistivity reduction techniques.

Therefore, there is a need to provide a VCSEL array design to increase resolution of structured light source for generating high resolution structured illumination for new and emerging applications in the areas of 3D imaging having better imaging resolution. There is a further need to provide such a structured light source in an imaging apparatus that is portable and at a low cost to widen the application range.

### SUMMARY OF THE INVENTION

In this invention recent innovations in VCSEL designs by some of the co-authors of this invention at Princeton Optronics Inc., Mercerville, N.J., also the Assignee of this application, are combined with innovative processing methods to construct VCSEL arrays that include very small diameter VCSEL devices with a comparable array pitch to provide a structured light source and a structured light projection apparatus that can project a high resolution structured illumination pattern at a large distance from the source.

More importantly, the structured light source using the new VCSEL array device/chip is compatible with surface mount assembly technology widely used for mounting electronic chips on printed circuit board thereby providing on-board compact portable 3-D imaging system. The design provided within the framework of this invention is modular, flexible, simple to implement and adaptable for volume manufacturing with surface mounting capability.

In one aspect of the invention a light source is provided to generate a high resolution structured illumination pattern and projecting a scaled image of the same on a plane distal to the light source for illuminating an object or a scene located therein, for reconstructing a high resolution 3-D image of the object and/or scene.

In another aspect, a high resolution structured illumination pattern is generated by configuring a densely or ultra-densely packed VCSEL array. In yet another aspect, individual VCSEL devices in the array are constructed to have very small emission windows of the order of 2-5 μm for better mode selection. Advantageously small size VCSEL devices are also beneficial in reducing the array pitch to 3-5 μm to construct densely or ultra-densely packed VCSEL array. In a further variation an array size of about 10×10 mm² includes 5,000 to 500,000 VCSEL devices. In a further aspect, small size of VCSEL devices allow high speed pulsed operation (<100 ps risetime) that is very desirable for generating/switching high resolution structured illumination pattern at high speed.

In yet another aspect of the invention different methods including reactive ion etching, oxidation, ion-implantation, dopant diffusion, and epitaxial regrowth to construct densely or ultra-densely packed VCSEL arrays is provided in different embodiments. These methods primarily create a current confining aperture or a current confining region in the VCSEL device. In preferred best practice modes of the invention each method may be applied alone or in combination with other methods to construct structured light source with desired emission shapes and patterns for illumination. More importantly, structured illumination patterns may be generated as a steady image or altered in a pre-programmed or dynamically programmed sequence.

In another aspect of the invention, customized structured illumination pattern may be generated by electrically connecting each VCSEL device to operate in individually addressable mode. In a variant aspect, each VCSEL device in an array are connected in pre-determined sub-array or groups, and each sub-array or group is individually addressable. In yet another aspect, individual groups are to be interleaved to generate structured illumination patterns in complex shapes and timing sequences. In a variant embodiment a plurality of arrays are arranged in a modular fashion to construct larger size arrays that are operated in any desired programming sequence to generate differently shaped structured illumination patterns at different times.

In a different variation, the emission properties imparted by the current confining aperture are augmented by an optical aperture for mode selection and stabilization. In a preferred mode of practicing the invention optical apertures are etched in a metallization layer providing one of the electrical contacts of the array. In one embodiment a transparent conducting oxide is used for a more uniform current distribution resulting in higher intensity and brightness in a densely or ultra-densely packed VCSEL array.

In one aspect of the invention high power and high brightness structured light source is constructed by using VCSEL devices that are specially designed with a plurality of gain segments separated by tunnel junctions to increase power in a single mode. Advantageously, VCSEL devices having high output power and high brightness are configured with two or three-mirrors. Arrays with regular shapes or other custom shapes are constructed where array pitch is uniform or non-uniform, or VCSEL devices in an array are distributed randomly.

In another aspect of the invention, a compact structured light source having surface mounting capability is constructed with integrated projection optics that is extremely suitable for integration with electronics devices including driver, light sensor, and image and signal processing functions on a common platform to realize a compact and portable on-board 3-D imaging system for applications like gesture recognition.

### BRIEF DESCRIPTION OF THE DRAWINGS

Different aspects of the invention describing a broad framework of the invention are presented in the specification which will be better understood and appreciated in conjunction with the drawing figures in which—

FIG. 1 is a schematic representation of a structured light projection apparatus using VCESL array as a structured light source;

FIG. 2 shows a schematic representation of a basic design of a monolithic VCSEL array configured using, a) two-mirror VCSEL devices and, b) external three-mirror extended cavity VCSEL devices;

FIG. 3 shows a cross section view of a current state of the art VCSEL array;

FIG. 4 shows a cross section view depicting a simple scheme for achieving densely or ultra-densely packed VCSEL array;

FIG. 5 shows a cross section view depicting a densely or ultra-densely packed VCSEL array with closely spaced VCSEL devices according to this invention;

FIG. 6 shows a cross section view depicting a densely or ultra-densely packed VCSEL array with closely spaced VCSEL devices according to this invention;

FIG. 7 shows a cross section view depicting a densely or ultra-densely packed VCSEL array with closely spaced VCSEL devices according to this invention;

FIG. 8 shows a cross section view depicting a densely or ultra-densely packed VCSEL array with closely spaced VCSEL devices according to this invention;

FIG. 9 schematically shows an alternative design for improved performance of VCSEL arrays shown in FIGS. 4-8, a) cross section view, and b) planar view;

FIG. 10 shows a planar view of a densely or ultra-densely packed VCSEL array constructed with differently shaped apertures shown in an expanded version of a section of the array;

FIG. 11 represents a densely or ultra-densely packed VCSEL array configured for individually addressable VCSEL devices positioned in, a) a regular array, and b) in a random array;

FIG. 12 represents a densely or ultra-densely packed VCSEL array configured for individually addressable, a) linear sub-arrays, and b) two-dimensional sub-arrays;

FIG. 13 represents a densely or ultra-densely packed VCSEL array configured for individually addressable connected group of linear sub-arrays that are interleaved;

FIG. 14 represents a structured light source module comprising a VCSEL array chip including a plurality of two-dimensional densely or ultra-densely packed VCSEL arrays;

FIG. 15 schematically shows densely or ultra-densely packed VCSEL array configured to generate differently shaped structured illumination patterns in addressable mode;

FIG. 16 shows images of projected structured illumination patterns recorded from a structured light source including a densely or ultra-densely packed VCSEL array at locations, a) closer to the source, and b) farther from the source;

FIG. 17 is a schematic representation of a 3-D imaging apparatus for gesture recognition application with a structured light source including a densely or ultra-densely packed VCSEL array is used for better image resolution;

FIG. 18 is a schematic representation of a compact structured light projection system comprising projection optics bonded to a structured light source with a densely or ultra-densely packed VCSEL array;

FIG. 19 schematically shows an integrated version of an on-board 3-D imaging system including a structured light projection system of FIG. 18 and electronic devices surface mounted on common platform;

### DETAILED DESCRIPTION

A broad framework of the principles used in configuring a structured light projection apparatus will be presented by describing various aspects of this invention using exemplary embodiments and represented in different drawing figures. For clarity and ease of description, each embodiment includes only a few aspects. However, different aspects from different embodiments may be used alone or in different combinations or sub-combinations, to implement the invention in various best practice modes. Other combinations and sub-combinations of the representative embodiments within the broad framework of this invention, that may be apparent to those skilled in the art but not explicitly shown or described, should not be construed as precluded.

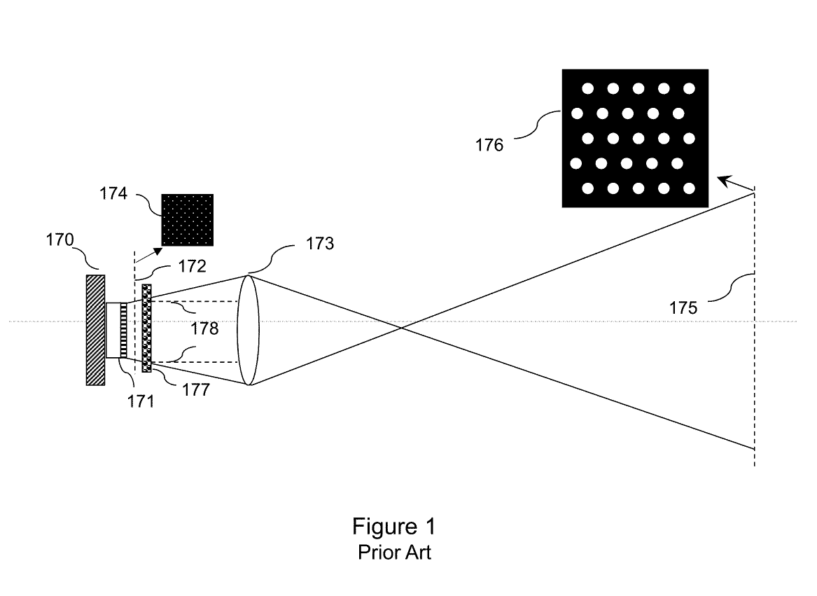

In a conventional 3-D imaging system, an object is illuminated partly or completely, using a two dimensional (2-D) illumination pattern (structured light), and an image of the object obtained back at a receiving device (a camera, photo-detector, etc.) located at the same plane as the light source, is electronically analyzed to determine the distance of each section of the object to create a 3-D image from the depth information. An illumination apparatus for generating a structured illumination pattern is shown in FIG. 1. A 2-D pattern as shown therein may be generated using a mask, a diffractive optical element, a light scanning device, or by using a 2-D array of light source, such as an array of Light Emitting Diode (LED), edge emitting lasers or VCSELs. VCSEL array is the most preferred source for its superior emission characteristics and adaptability for large scale manufacturing.

Referring now to FIG. 1, a basic structured light projection apparatus includes a light source and a projection apparatus. In the example shown in FIG. 1 the light source is a VCSEL array 171 mounted with peripheral accessories that include electronic drivers etc., on a submount 170. The light emitted from individual VCSEL devices in the VCSEL array intercepted at any plane 172 for example, exhibits a dotted pattern 174 (shown as bright spots in a dark background in the inset) comprise a structured illumination source. The shape and size of the structured illumination pattern represents the shape and size of the VCSEL array and the pitch of the structured illumination pattern (spacing between adjacent beams) is proportional to the pitch of the VCSEL array (spacing between adjacent VCSELs in the array) and the distance to which the structured illumination pattern is projected.

The structured light is projected on to a region in physical space to illuminate an object or/and a scene positioned at a plane 175 for example, using a projection apparatus, which in a simple form could just be a projection lens 173, or more sophisticated optical arrangement positioned at an appropriate distance from the VCSEL array. The structured illumination pattern 176 in a planar view replicates the combined emission pattern from the VCSEL array.

And while the example shown here is a plurality of illuminated spots arranged in a simple grid, structured light source having other patterns, shapes and sizes may also be generated and will be described later. Further improvement to the structure illumination pattern may be achieved by placing optional optical elements for example, a microlens or an array of microlenses 177 in front of the VCSEL array 171 to increase the size and brightness and making the emitted beam (shown with dashed lines 178) less divergent. Additional optical elements facilitate projecting structured illumination patterns over a longer distance while preserving adequate illumination intensity, image quality and resolution.

### State of the Art VCSEL Source:

Typical VCSEL device constructed on a semiconductor substrate comprises a top first semiconductor multilayer DBR mirror and a bottom second multilayer DBR mirror forming the laser resonant cavity. One of the mirrors is made partially transmitting and provides the output laser beam. In between the mirrors is a gain region which includes a group of quantum wells and an aperture. The aperture confines the drive current in the central region to maximize gain in the quantum wells in the same area as the optical mode. The aperture also restricts the optical mode to an emission window region etched in one of the electrical contact metallization layer. The aperture size in relationship with the other properties of the laser resonant cavity determines the transverse mode properties such as single mode versus multimode emission, etc.

The gain and power capacity of the VCSEL device can be increased further by providing multiple groups of quantum wells in the gain region. Each group of quantum wells has an aperture associated with it to confine the current and the optical mode in the same region to obtain high gain and power transfer into the optical mode. An important element is needed in between each group of quantum wells which transmits the charge carriers. This comprises a tunnel diode which allows carriers to tunnel through the p-n junction. The technology for arrays of high brightness VCSELs have been disclosed in a U.S. patent application Ser. No. 14/700,0010 filed by Wang et al. on Apr. 29, 2015 which is also assigned to Assignee of this application. Contents of that application co-authored by some of the inventors of this application, and co-owned by Princeton Optronics Inc. Mercerville, N.J., is being incorporated by reference in its entirety.

The use of more quantum well groups increases the power in the VCSEL in both single mode and multimode configurations. However to restrict the operation to single mode, the diameter of the aperture(s) have to be small so that the higher order modes are attenuated. In order to further increase the power in single mode operation and increase the brightness the laser cavity parameters have to be changed to increase the single mode diameter to draw power from a larger volume of the multiple groups of quantum wells. One of the cavity parameters to achieve this is the cavity length. Increasing the cavity length increases the diameter of the lasing modes and means a larger aperture can be used to control single mode operation thus increasing the gain volume to obtain higher power and brightness.

The VCSEL laser cavity length is increased by introducing a third mirror which can be placed at a prescribed distance away from the basic VCSEL epitaxial two mirror structure, where one of the DBR in combination with the third mirror forms an equivalent mirror for the laser cavity and increases the cavity length to the distance between the third mirror and the other VCSEL DBR mirror. Several embodiments of the three mirror cavity can be formed which either use a separate mirror, a mirror which is bonded directly to the VCSEL substrate or by depositing a mirror coating on the VCSEL substrate surface opposite the VCSEL epitaxial structure.

The combination of the multiple groups of quantum wells in the gain region and the use of the three mirror resonant cavity structure increases the single mode power and thus the brightness of VCSEL devices by more than two orders of magnitude. The use of a third mirror to increase the brightness of a VCSEL element is equally applicable to VCSEL arrays and a single mirror can be used as the third mirror for the whole array.

In general, a VCSEL optical mode is generated with random polarization unless there is some residual optical anisotropy in which case it will lase in a linear polarization. One approach that is known in the art is to use an elliptical aperture or similar means to cause sufficient anisotropy in the VCSEL resonant cavity to force a linear polarized mode. Other methods such as using polarization restricting mirrors or components with external cavity VCSELs can also be used.

### VCSEL Array as a Structured Light Source:

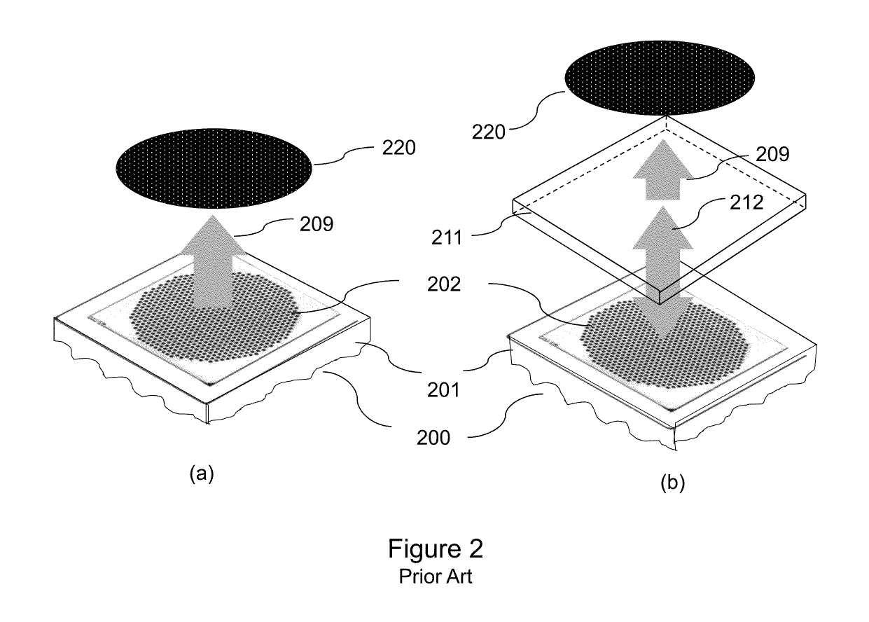

The invention may be practiced using light sources comprising prior art VCSEL arrays including high power VCSEL devices including self-emitting two-mirror and, integrated three-mirror and external three-mirror, extended cavity VCSEL devices that are well known in the art for their improved high power performance. Examples of prior art light sources that can be used as a structured light source are described in the context of 3-D imaging apparatus in the U.S. patent application Ser. No. 14/303,161 filed on Jun. 12, 2014, by Ghosh et al., co-authored by some of the inventors of this application and co-owned by Princeton Optronics Inc., Mercerville, N.J., also the Assignee of this application. The content of above referenced application is incorporated by reference in its entirety. More specifically, the VCSEL device configurations shown in top and bottom emitting modes respectively, in FIGS. 1 and 2, and described in paragraphs [0038]-[0053] therein, are being incorporated by reference. That description is being incorporated by reference herein. VCSEL devices having these configurations are suitable for structured light source.

For higher gain and output power capacity and high brightness, a different VCSEL design having multiple groups of gain regions, each group including single or multiple quantum wells is a more preferred choice. An exemplary design for a high power and high brightness VCSEL is described in the U.S. patent application Ser. No. 14/700,010 filed on Apr. 29, 2015, by Wang et al., co-authored by some of the inventors of this application, and co-owned by Princeton Optronics Inc. Mercerville, N.J., also the Assignee of this application, contents of said application is being incorporated by reference in its entirety.

The basic concepts incorporated in a particular type of high power and high brightness VCSEL device in self-emitting two-mirror, integrated three-mirror and external three-mirror extended cavity modes shown in FIGS. 2, 3, 4 and 5 is described in paragraphs [0056]-[0069] in the above mentioned co-owned application. That description is being incorporated by reference herein. More specifically, in this particular design, each group of quantum wells has an aperture associated with it to confine the current and the optical mode in the same region to obtain high gain and power transfer into the optical mode. In between each group of quantum wells is a tunnel diode which allows carriers to tunnel through the p-n junction. This configuration of VCSEL devices is adaptable for excellent polarization control.

While the basic VCSEL designs that can be used for a structured light source are explained using a single device, these concepts are easily adaptable for constructing VCSEL arrays either monolithically or by hybrid integration with external third mirror using a foreign substrate, preferably a transparent substrate to include the third mirror that is bonded to the monolithic VCSEL array at a wafer scale. The technology for arrays of high power and high brightness VCSELs is described in the above cited U.S. patent application Ser. No. 14/700,010 filed on Apr. 29, 2015, by Wang et al. That description is being incorporated by reference herein.

A typical example of a two dimensional VCSEL is shown in FIG. 2. An array 200 comprise a plurality of individual VCSEL 202 (each dot on the surface of the array 200, only one labeled for clarity) built on a common substrate 201. More specifically, FIG. 2a shows an array that may be constructed using a plurality of self-emitting two-mirror VCSELs or integrated three-mirror extended cavity VCSELs (third mirror not shown in this depiction). The third mirror may be integrated with the VCSEL array by applying a mirror coating on the substrate surface opposite to the VCSELs or a separate mirror bonded to the VCSEL array. The exemplary VCSEL array shown in FIG. 2b is configured using an external third mirror 211 aligned and positioned at a pre-determined distance above the VCSEL array 200. The laser emission 212 is generated between the lower mirror (not shown here for clarity) and the external third mirror 211 which is partially reflecting and transmits the radiation in an upward direction shown as thick arrow 209 in FIG. 2b.

Combined emission pattern generated by the VCSEL array replicates the shape (in 2-Dimensional space) of the array and individual beams from each VCSEL are arranged according to the individual VCSELs positioned in the array pattern. For example, the combined beam from a circular array would generate a circular beam profile 220 (in 2-D) where each bright dot represents emission from each VCSEL device in the array. The combined emission thus provides a structured illumination pattern comprising a grid of individual beams. In this particular example the collective emission would appear as an array of bright dots.

In a typical VCSEL, the beam emitted has a circular profile conforming to the shape of the current confining aperture of each VCSEL device, which is most commonly is in the shape of a ring. It is noted that in a VCSEL array as shown in this example, all the VCSELs need not be operated at the same time. Each VCSEL may be operable as individually addressable device or in pre-determined groups, clusters or sub-arrays in a pre-determined timing sequence, depending upon the mode or method of imaging. In other applications, group, cluster or sub-array may be dynamically configurable.

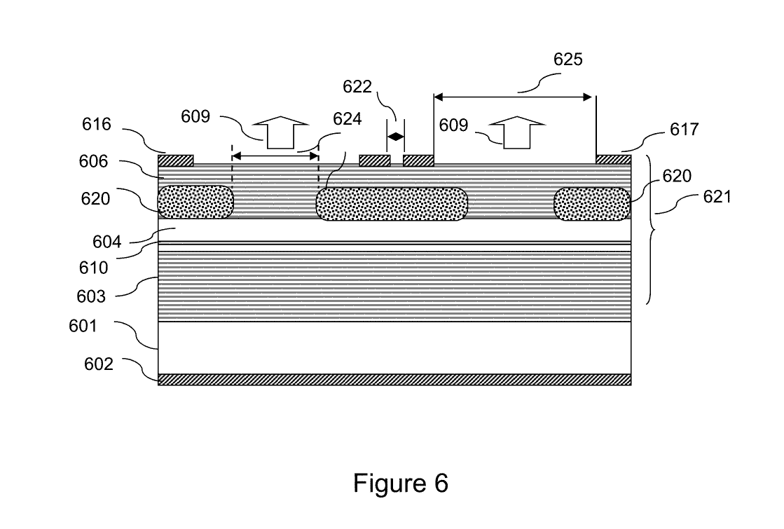

Additional beam shaping may be achieved by combining optical elements either integrated with individual VCSEL devices or collectively with the array, such that the structured light generated by the entire array is more focused and sharper for improving resolution. In the U.S. patent application Ser. No. 14/303,161 filed on Jun. 12, 2014, by Ghosh et al., co-authored by some of the inventors of this application, also co-owned by Princeton Optronics Inc., Mercerville, N.J., also the Assignee of this application, the concept is described in reference to FIG. 6 in paragraphs [0069]-[0070] in the above mentioned co-owned application. That description is being incorporated by reference.

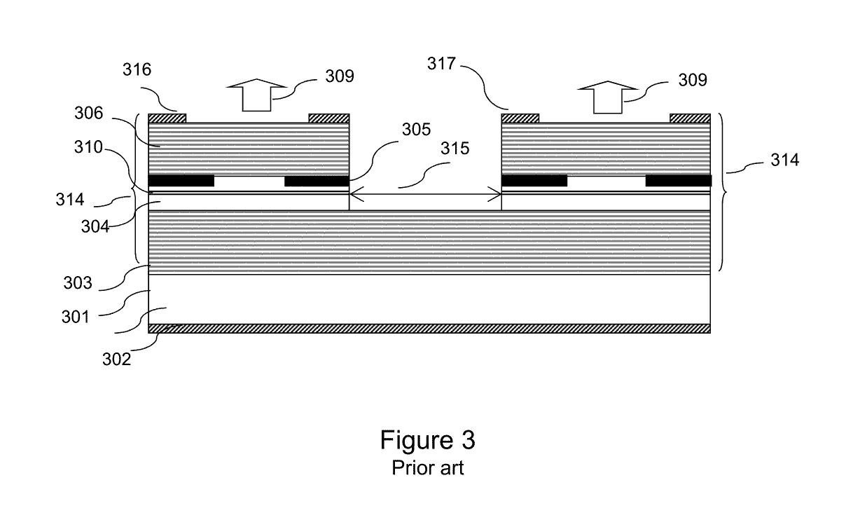

One advantage of using VCSEL in a structured light source is that a large number of VCSEL devices can be constructed monolithically on a single substrate, and integration with external third mirror can be achieved in a wafer scale processing which is very attractive for high volume manufacturing. While the limitations of a prior art VCSEL array will be explained in reference with a typical self-emitting two-mirror configuration of VCSEL device, same concepts are pertinent to other three-mirror extended cavity VCSEL devices. FIG. 3 shows a cross section of a prior art VCSEL array where only two devices are shown for ease and clarity of description to follow. It should be noted that same concepts apply to a larger size linear array or a two dimensional array having many VCSEL devices. A VCSEL array comprise a basic multilayer semiconductor structure collectively shown as 314 (VCSEL structure hereinafter) grown epitaxially on a single substrate 301 (GaAs or InP) wafer that may be as large as 6″ in diameter. More often, the entire structure (stack) is grown sequentially in a single growth run (in a single pump down sequence without exposing the structure to outside environment).

The VCSEL structure includes a bottom Diffraction Bragg Grating (DBR) to form a first mirror 303, a gain region 304 which includes one or more quantum wells 310 as per the VCSEL design criterion and a top DBR mirror 306. An additional layer 305 (aperture layer hereinafter) having a special composition is grown between the gain region and the upper DBR (306, more preferred) or between the gain layer and the bottom DBR (203). The composition of the aperture layer is selected such that it oxidizes relatively rapidly as compared to the other layers in the stack. Regions for individual VCSEL devices are defined by standard photolithography and separation between adjacent VCSELs is achieved by chemically etching mesas through the epitaxial layer down slightly below the aperture layer 305, for example, to a lower confinement layer (not shown) or to the lower DBR. The entire stack is placed in a controlled oxidation environment to rapidly oxidize the aperture layer from the exposed sides of the mesas. An exemplary process is described in the U.S. patent application Ser. No. 14/634,902 by Wang et al. on Mar. 2, 2015, co-authored by some of the inventors in this application, and co-owned by Princeton Optronics Inc. Mercerville, N.J., also the Assignee of this application. Content of the above mentioned application is being incorporated by reference in its entirety.

The oxidation proceeds inwards from the side walls of the mesas and the oxidation environment and the oxidation time is controlled to arrest oxidation process to achieve a desired thickness (from the sides of the mesas) of the oxide layer leaving an area in between that is not oxidized (defines the area where current flows and gain and laser emission occurs). While this particular example shows an aperture with a circular geometry, apertures of other shapes including random shapes may also be created. The areas that are oxidized around the center of the mesas have a higher electrical resistance as compared to the non-oxidized region enclosed in the annular oxidized region to allow current flow to be restricted within the aperture (hence current confining aperture).

Current source is typically connected between a top contact to each device 316, 317, etc. and a bottom contact 302 applied contiguous to one surface of the substrate that is opposite to the VCSEL devices. While the bottom contact in this particular example is common to all the VCSEL devices, it need not be always so and other alternative arrangements are equally applicable. Although other methods such as masking parts of the mesa edge could be envisioned, creating a differently shaped current confining aperture is the most preferred one for densely and ultra-densely packed VCSEL arrays as will be described later.

In one embodiment where the VCSEL devices in the array are to be operated together, all the top contacts 316, 317, etc. may be electrically connected together using a contiguous top metallization having emission windows open over the aperture area for the light to be emitted. The thick arrow 309 represents laser emission collectively in an upward direction in this depiction. It should however be noted that although the top and bottom contacts in this particular example cover the entire top and bottom surfaces, current flow and therefore gain is confined within the aperture region. As a result, lasing action hence light emission and dominant optical mode are also confined in this region. It is further noted that in the simplest design, windows on the contiguous top metallization layer substantially align with the current confining aperture in physical space, and therefore dominant optical mode is also confined in this same physical space. Advantageously, both the current confining and optical mode confining apertures are created using a single masking step, which is very conducive to high volume manufacturing process.

In a bottom emitting mode, the role of the top and bottom contacts are just reversed with the emission windows etched in the substrate metallization (302), such that the VCSEL side of the stack which generates more heat during laser emission may be covered contiguously to have a larger physical area closer to a heat dissipating surface such as a heat sink for better thermal management. The bottom emission mode is particularly preferred for high power VCSEL devices. In other embodiments the substrate thickness is reduced or removed completely for preventing laser radiation to be absorbed back in the substrate and/or for better thermal management. These and other variations are known in the art as matter of packaging choices depending upon the application space.

An important parameter that determines the resolution of a structured illumination pattern is the array pitch 315 which in turn depends on the resolution of the etch process, oxidation process parameters and thermal management considerations. From all these considerations, spacing in state of the art VCSEL arrays is typically 3 times the mesa diameter of the individual VCSEL devices. For a commonly used mesa diameter of about 5 μm (micrometer), a lower limit of the spacing is about 15 μm. For a structured light source for high resolution 3-D imaging of small objects, typical spacing of about 15 μm in currently available VCSEL array would severely limit imaging resolution, and in particular, when the object being imaged is small, located at a large distance, in low visibility surroundings (e.g. in low background light, fog, cloud, etc.) from the structured light source.

### High Resolution Structured Light Source:

Better 3-D image resolution may be obtained by using a structured light source having VCSEL devices with smaller emission diameter to improve optical mode confinement, or/and by incorporating more VCSEL devices in a smaller surface area. One way to improve resolution of a structured light source is to reduce the array pitch (defined as the distance between adjacent VCSEL devices in a VCSEL array) as much as possible. In an exemplary densely or ultra-densely packed VCSEL array chip constructed according to this invention about 5,000 and 500,000 VCSEL arrays are constructed in an area of 2×2 mm² and 10×10 mm², respectively. It is noted that proportionally, about equal amount of area is needed to accommodate contact pads at the periphery/perimeter of the chip in either case.

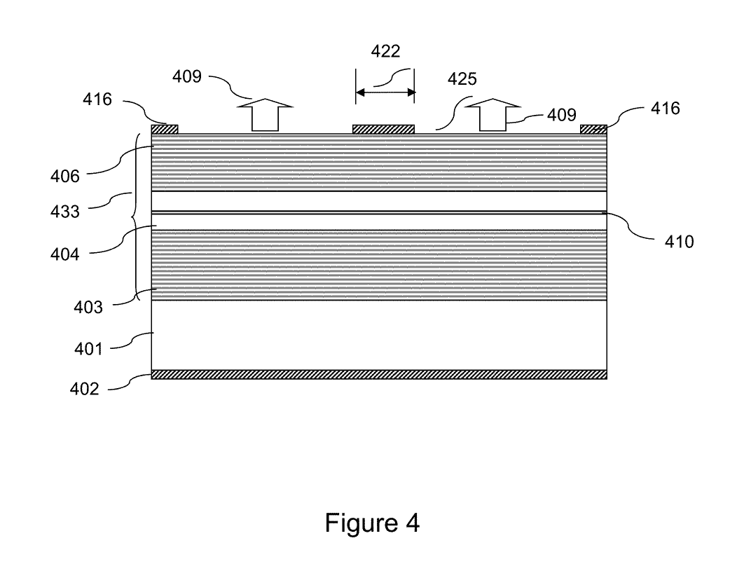

In a simplest form, densely or ultra-densely packed VCSEL arrays are formed by etching windows in one of the electrical contact layers. One such exemplary embodiment for a top emitting configuration of a VCSEL array is shown in FIG. 4. Epitaxial layers are grown on a substrate 401 to create a basic VCSEL device structure 433. Similar to a prior art device, a basic VCSEL structure includes a bottom DBR mirror 403, a gain region 404 with one or more group of quantum wells 410 and an upper DBR mirror 406, which typically has high electrical conductivity. The basic structure does not include an aperture layer because there is no current confining aperture in this particular design. Instead, contiguous electrical contact metallization layers 402 and 416 are applied respectively, to the bottom surface of the substrate and the top surface of the upper DBR 406. The top metallization layer is made quite thick and emission windows 425 are etched to allow for the laser light 409 to be emitted out from the window regions.

Since there are no mesas etched to create current confining apertures, the distance 422 between adjacent emission windows can be reduced significantly to facilitate emission from individual VSCEL devices to be positioned in a small array pitch. In an alternative arrangement, windows may be etched in the bottom metallization layer 402 (for VCSEL array configured in bottom emission mode) and the top metallization 416 remains contiguous. One disadvantage of this particular configuration is that the drive current applied between the top and bottom electrical contact (416 and 402, respectively) generates gain in the entire epitaxial structure including the areas that are covered with electrical contact metallization 416.

Since the entire structure experiences gain laser emission takes place throughout the structure. However, a significant amount of light emitted under the electrical contact layer in the gap (422) between the adjacent VCSEL devices are lost due to the thick electrical contact metallization in those regions. As a result, a structured illumination pattern of lighted areas interspersed with less lighted regions is generated. Although very densely packed array with significantly reduced array pitch is achieved in a relatively simple processing sequence, this is the least preferred embodiment because emission efficiency is relatively low due to a significant portion of light being obscured by the metallization layer.

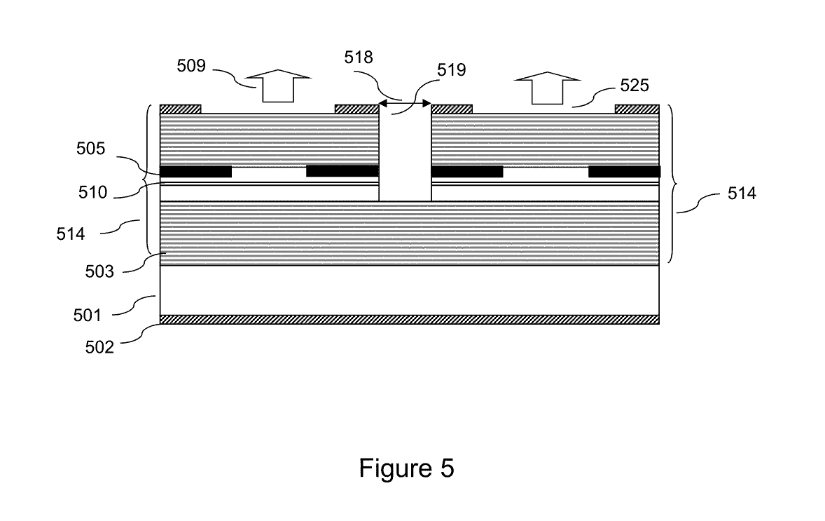

A better structured light source having high resolution may be configured using an alternative processes to construct densely or ultra-densely packed VCSEL arrays according to this invention. In one exemplary embodiment of the invention a high density VCSEL array having significantly lower spacing between the adjacent VCSEL devices is provided. FIG. 5 represents an embodiment where the spacing between adjacent VCSELs is reduced by adapting a different processing sequence. Different elements in FIG. 5 are labeled similar to equivalent elements in FIG. 3, and the description in reference to FIG. 3 is equally applicable. That description will not be repeated for brevity. The gain region 510 shown here includes only one group of quantum wells, but the design is readily adaptable to include more groups of quantum wells for high power and high brightness VCSEL devices described earlier in the subject matter incorporated by reference from the U.S. patent application Ser. No. 14/700,010 filed on Apr. 29, 2015, by Wang et al.

Very small emission regions for individual VCSEL devices are defined using high resolution photolithography which also allows a smaller array pitch 518 (separation between the adjacent VCSEL devices). Mesa diameter smaller than 5 μm is achieved by this process for high resolution structured light source. In this process, the mesas in the VCSEL structure 514 are etched down to the aperture layer 505 using reactive ion beam etching (RIE). The combination of high resolution lithography and RIE allows very narrow and sharp trench (519) to be created between adjacent VCSEL devices. The current aperture 505 is formed by controlled oxidization of the aperture layer in a process similar to that described in reference with FIG. 3.

In a different embodiment of the invention, the current confining aperture may be created by alternative process described in reference with FIG. 6. Elements in the drawing figure that are equivalent to the elements in FIGS. 3 and 5 are labelled identically and the description of these elements is pertinent in the context of FIG. 6 as well. In this embodiment of the invention, the VCSEL structure collectively shown as 621 is grown in a similar fashion as described in reference to FIGS. 3 and 5, except for the aperture layer (305 and 505). In this particular process, the aperture layer is not required because the current confining aperture to electrically separate individual VCSEL devices in an array is created by ion implantation instead of controlled oxidation.

As shown in FIG. 6, epitaxial layers for a VCSEL device structure 621 similar to the one described in reference with FIG. 3, are grown on a substrate 601 forming the basic device structure, except for the oxidation layer. More specifically, the structure includes a bottom DBR mirror 603, a gain region 604 with one or more groups of quantum wells 610 and a top DBR mirror 606, respectively, in that order. Using high resolution photolithography, implant regions with sub-micron accuracy are defined in the upper DBR 606 to create current confining apertures regions 620 therein using ion implantation. The ion implanted regions have high electrical resistance thereby restricting current flow only in the non-implanted regions 624. Advantageously, in some embodiment of the invention, apertures other than circular and even of random shapes may easily be incorporated using the ion-implantation method. Utility of apertures having arbitrary shapes will be discussed later.

Electrical contacts (616, 617, etc.) to each VCSEL device are fabricated on the top surface (with respect to the figure) as a contiguous metal layer having emission windows 625 etched therein for collective operation of all the VCSEL devices in this exemplary array. The bottom surface of the substrate is used to apply a second electrical contact metallization 602, which in this representation is common to all the VCSEL devices. However, an array may be configured in bottom emission mode as has been described in reference to FIG. 3.

It is important to note that the process does not require etching to form mesas. As a result, the array pitch 622 may be reduced considerably as compared to the embodiments shown in FIGS. 3 and 5 where mesas were etched to electrically isolate the adjacent VCSEL devices. The adjacent windows 625 located between the ion-implanted regions (620) may thus be quite closely spaced. As a result, laser emission 609 from adjacent VCSEL devices is very close together, thereby improving resolution of the structured illumination pattern. For example, VCSEL devices having emission window as small as 2 μm in diameter with an array pitch as small as 3 μm may be achieved in an exemplary VCSEL array constructed with ion implanted current confining apertures according to this invention.

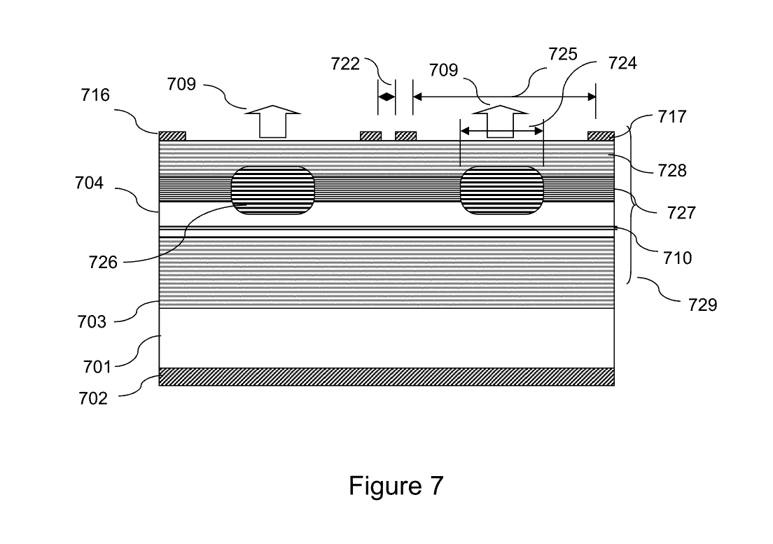

A different process to create densely packed VCSEL arrays will be described in reference with an embodiment of this invention shown FIG. 7. Various elements in FIG. 7 are labeled in a similar fashion as in FIG. 6 and the description of those elements in reference with FIG. 6 is equally applicable in the context of FIG. 7 as well. More specifically, epitaxial layers for a VCSEL device structure shown collectively as 729 are grown on a substrate 701 forming the basic device structure. The basic structure includes a bottom DBR mirror 703, a gain region 704 with one or more groups of quantum wells 710, and a top DBR mirror. The top DBR mirror in this particular design is constructed in two parts including a lower section 727 having low electrical conductivity and an upper section 728 having a high electrical conductivity, in that order, such that the top DBR exhibits differential current flow in the two sections.

Using high resolution photolithography, regions with sub-micron accuracy are defined on the surface of the upper section (728) of the top DBR to create current confining apertures 726 (only one labeled for clarity). A suitable dopant (for example, zinc for a p-type DBR material) is diffused to selectively make the aperture region of the lower section of the DBR 727 highly conducting. The dopants may be diffused in the lower section 727 prior to the epitaxial growth of the upper DBR section 728, or alternatively, after both DBR sections (727 and 728) are sequentially grown. The high electrical resistance in the lower section 727 of the DBR mirror around the aperture region 726 forces the electrical current to funnel through the diffused high conductivity aperture region 726 (hence current confining aperture).

Since there is no etching needed to form the mesas the array pitch 722 may be reduced significantly. In this particular example a contiguous metallization layer is applied on the top surface for electrical contacts 716, 717, etc. to the VCSEL devices, whereas the second contact to the VCSEL devices is a contiguous metallization layer 702 on the bottom surface of the substrate 701. Although drive current is applied in a larger peripheral area 725 on the top surface, the current flows (funnels) through the smaller region 724 aligned centrally (only one set labeled for clarity) with the current confining aperture 726. Since the emission windows 725 are closely spaced, laser emissions 709 from individual VCSEL devices are at a very small pitch, thereby improving resolution.

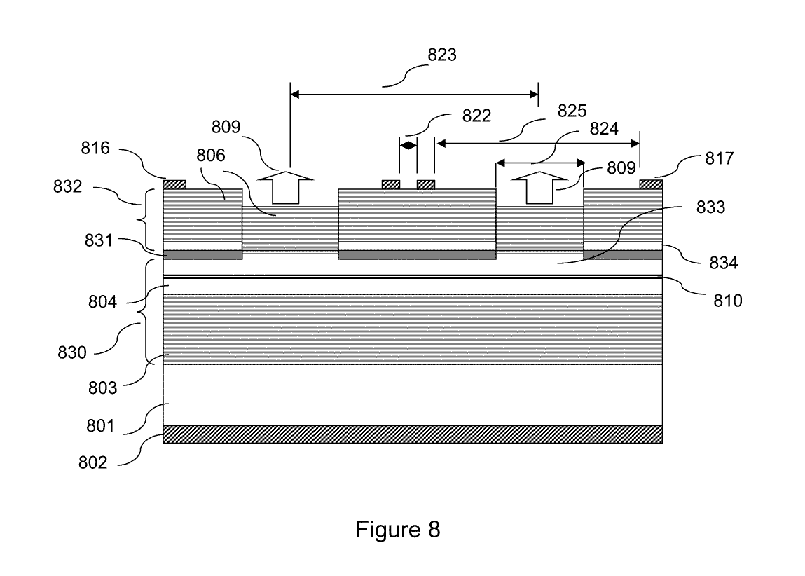

In one embodiment of the invention VCSEL arrays are constructed using an epitaxial regrowth process to create current confining apertures for a densely or ultra-densely packed VCSEL array. The process will be described in reference with FIG. 8. Epitaxial layers to construct a VCSEL structure is executed in two steps. In a first step, a partial multi-layer epitaxial structure 830 is grown on a substrate 801 (to be referred as the bottom epitaxial structure hereinafter). The bottom epitaxial structure includes a bottom DBR mirror 803 and a gain region 804 including one or more groups of quantum wells 810. An insulator layer 831 is deposited or grown on the epitaxial structure. Using photolithography, apertures 833 are etched in the insulator layer, followed by a second epitaxial structure 832 (upper epitaxial structure hereinafter) growth to complete the VCSEL structure. The upper epitaxial structure includes an interface layer 834 and a highly conducting top DBR mirror 806, respectively.

Electrical contacts 816, 817, etc. and 802 are applied respectively, on top and bottom surfaces in a substantially similar structure as described before in reference with FIGS. 3, 4, 5, 6 and 7. Drive current applied between the top and bottom electrical contacts forces the current to funnel through the apertures 833 as the insulator layer 831 blocks the current flow around the aperture regions. Since the apertures are formed using photolithography and regrowth processes (no etching), the array pitch 822 may be made very small. The emission windows 825 of the individual VCSEL devices may also be made quite small such that output 809 emitted from the individual VCSELs are closely positioned in the collective structured light emission from the VCSEL array. In one exemplary embodiment emission window may be ˜2 μm and the array pitch may be as small as ˜3 μm.

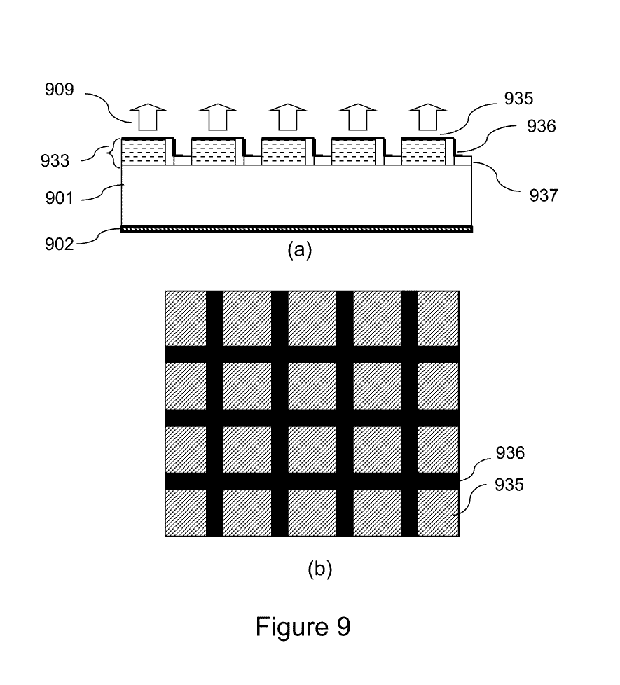

In the embodiments described above, the VCSEL emission is provided through windows in the top electrical contact metallization layer, such that output beams are not blocked by the opaque metallization layer. A particular limitation of this design aspect is that current flowing from the side of windows in the electrical contact layer into the current confining aperture that in some instances (depending on other design parameters) may limit the performance of the VCSEL array by adversely affecting the radiation intensity distribution in the output beam. In an improved design, this limitation is remedied in an exemplary embodiment of the invention shown in FIG. 9, depicting a cross section and a planar view of an exemplary VCSEL array (FIG. 9a and FIG. 9b, respectively).

Similar to the other embodiments shown in FIGS. 3-8, the VCSEL arrays shown in FIG. 9a includes an epitaxial structure 933 having top and bottom DBR mirrors and a gain region of one or more groups of quantum wells fabricated on a substrate 901. The VCSEL array is processed in substantially similar fashion as described in reference with FIG. 5. Prior to applying the electrical contact layer (516. 517 etc. in FIG. 5) to the top surface of the upper DBR (506 in FIG. 5) an electrical insulator 937 followed by an electrically conducting material 936 is applied in the gaps between the adjacent mesas. In a planar view shown in FIG. 9b these regions appear as a dark grid 936.

A layer of transparent electrical conducting material 935 such as indium tin oxide (ITO) or other similar transparent conducting material known in the art is applied to the top surface of the VCSEL array. The metal grid 936 in electrical contact with the transparent electrical conductor layer 935 provides the top electrical contact to the VCSEL devices in the array. In effect, the emission window (for example, 525 in FIG. 5) is covered with the transparent conducting material. A drive current is applied between the metal grid 936 and the bottom electrical contact layer 902 and the VCSEL emission 909 exits the array through the transparent conducting region 935.

The insulating layer 937 applied around the mesas eliminate the need for the current confining aperture (505 in FIG. 5). However a current confining aperture may optionally be used to impart other beneficial optical properties to the VCSEL emission characteristics as has been described in the U.S. patent application Ser. No. 13/337,098 by Seurin et. al., filed on Dec. 11, 2011, co-authored by some of the inventors of this application and co-owned by Princeton Optronics Inc. Mercerville, N.J., also the Assignee of this application. The content of that application is being incorporated by reference in its entirety. While the embodiment shown in FIG. 9 is described in reference to the VCSEL array shown in FIG. 5, the same concept of applying a transparent conducting material on the emission window is equally applicable to other densely packed VCSEL array shown in embodiments in FIGS. 4, 6, 7 and 8 as well.

In the examples of the densely and ultra-densely packed VCSEL arrays described so far, the VCSEL array has been depicted as a regular array where the array pitch is uniform. Collective emission from a structured light source so configured emits a plurality of beams that create a structured illumination pattern similar to a dot matrix on a grid (as shown in FIG. 2) where the grid spacing is defined by the array pitch. There are many different arrangements that the VCSEL arrays can be configured to form a structured illumination pattern. For example, a structured light source may be configured to have a pre-determined variation in the array pitch across the entire or part of the array such that different parts of the structured illumination pattern illuminate different parts of the object/scene with different resolution in space and time. Furthermore, the VCSEL array may be arranged in different shapes, geometric and non-geometric including random shapes that would determine the shape of the region illuminated by the structured light source.

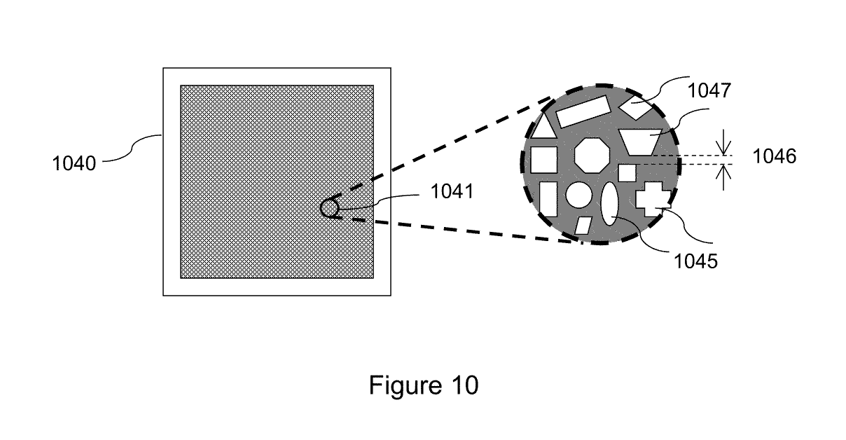

In the examples of structured light source described so far, the current confining apertures are assumed to be generally circular in shape for the ease of explaining the basic concepts of the invention. The emission from a VCSEL device having a circular current confining aperture typically results in a beam that is circular in shape. It is documented in the co-owned U.S. patent application Ser. No. 13/337,098 by Seurin et al., filed on Dec. 24, 2011, and incorporated by reference in this application. In a different aspect of the invention, structured light source to generate different shapes of structured illumination pattern is achieved by custom designing the current confining aperture having different shapes as shown in FIG. 10. The concept is also used in a different context in the prior art United State Patent Application No. 2912/0281293 by Grönenborn et al., published on Nov. 8, 2012, where without having to physically change a pattern defining mask, the shape of an emission beam on an image plane changes by switching to different VCSEL arrays having differently shaped apertures. However, not all shapes can be generated at the same time at the same physical space.

Referring now to FIG. 10, there it shows a planar view 1040 of a structured illumination pattern from a structured light source including a plurality of VCSELs having differently shaped current confining apertures. The inset shows an expanded view of a small section 1041 of the structured illumination pattern from such a structured light source. The current confining apertures with a multiplicity of shapes 1045, 1047, etc. are arranged randomly while keeping the distance between the adjacent VCSEL devices 1046 in the array to be as small as in the structured light source described earlier.

The example of shapes, sizes and layout shown in FIG. 10 is only illustrative for the ease of description and should not be construed as limiting. Advantageously, different combinations of shapes, sizes, and layouts of the current confining aperture are easily incorporated in the methods described earlier to construct current confining apertures in reference with FIGS. 5, 6, 7 and 8. It is important to note that according to the concepts of this invention, all different shaped beam patterns may be generated simultaneously. Therefore, variations in selecting shapes and sizes of apertures may be used as a design parameter to achieve desired custom structured illumination patterns. All such variations are included within the broad framework of the concept.

In the densely and ultra-densely packed VCSEL arrays described so far in FIGS. 5, 6, 7 and 8, all the VCSEL devices are shown to be electrically connected to operate in parallel such that the structured illumination pattern is a plurality of bright spots on a grid (similar to that shown in FIG. 2, for example). In practice, that is not the only structured illumination pattern that can be generated using a densely and ultra-densely packed VCSEL array. Electrical connection of individual VCSEL devices in an array is another factor that determines the structured illumination pattern generated by a VCSEL array. For example, in an array, each VCSEL device may be individually connected, such that each VCSEL device is operated separately, or a pre-determined number of VCSEL devices may be operated as a group, or one or more groups of VCSEL devices are operated as a larger group, or parts of different groups are operated interleaved with at least one other group. A second factor that adds variation to the structured illumination pattern is the order or timing sequence in which individual VCSEL devices or a group of VCSELs in an array are operated.

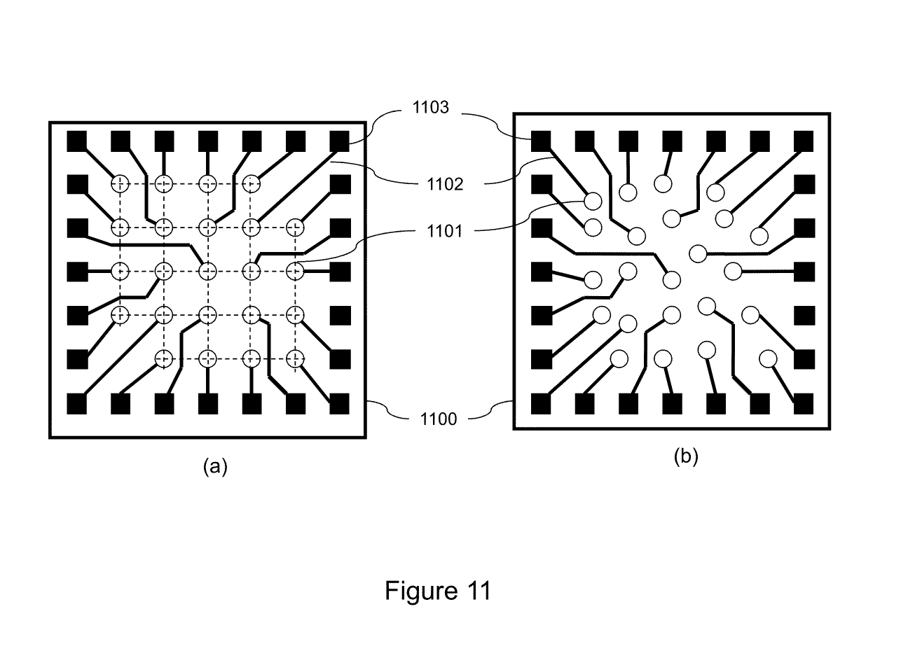

In FIGS. 11-15, examples of different modes of electrically connecting the VCSELs in an array are shown. Although, only small sections of an array are shown, these examples are merely illustrative of the concepts and should not be construed as limiting. Referring now to FIGS. 11a and 11b, there it shows planar view two different types of VCSEL array chip layout 1100 including a plurality of individual VCSEL devices 1101 (only one set labeled for clarity). More specifically, in the configuration shown in FIG. 11a, all the VCSEL devices lie on a regular grid shown as thin dashed lines having a fixed pitch (a regular VCSEL array), whereas in the configuration shown in FIG. 11b the VCSEL devices are placed in a random 2-D arrangement (irregular VCSEL array). Other regular array patterns or other randomly distributed arrangements in specific shapes and sizes are equally applicable to construct a structured light source.

Each VCSEL device is connected to a respective bonding pad 1103 located on the periphery of the chip using a corresponding metal connector 1102 on the common substrate for high speed operation (only one set labeled for clarity). Alternatively, a wire bonding from a VCSEL to a bonding pad on the periphery may be used. The other common electrical contact of each VCSEL is located on the other surface of the chip (not shown here). Each VCSEL device in this configuration is individually addressable; however, all the VCSELs or a select group of VCESLs either in a sub-array (FIG. 11a) or located randomly (FIGS. 11a and 11b) may be addressed as a sub-group. In another embodiment, both the metal contacts may be formed on the same surface to facilitate surface mounting of the VCSEL array chip on a submount including a thermal submount, a printed circuit board (PCB), or any other common platform devised for a particular structured light application.

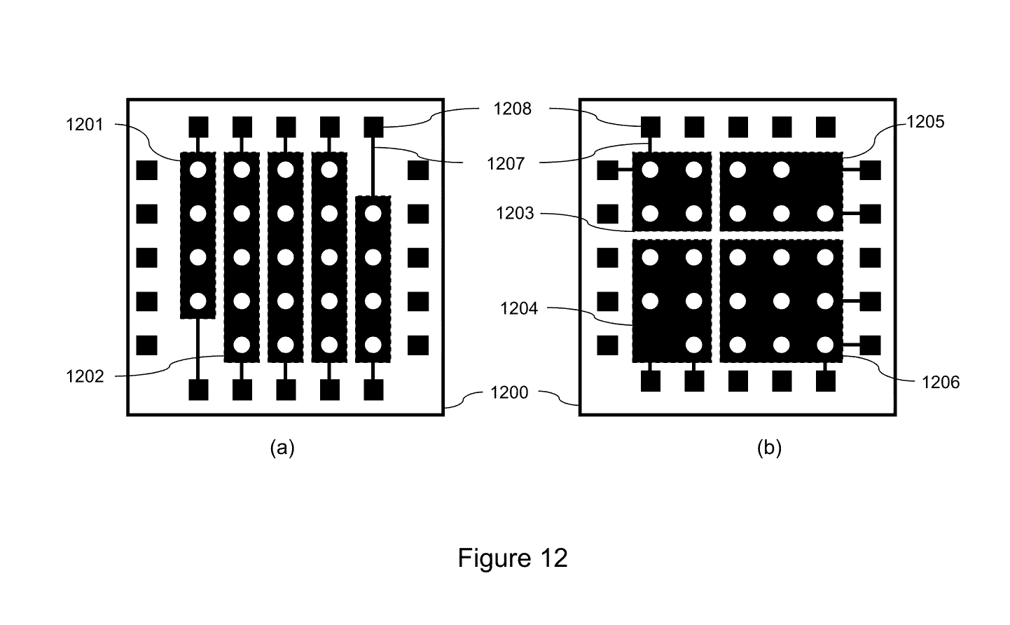

Referring now to FIG. 12, there it shows examples of VCSEL array chips 1200 where individual VCSEL devices are electrically connected in independently addressable sub-arrays. In particular, FIG. 12a shows individual VCSEL devices (represented as white dots) that are electrically connected in groups, for example, as a linear sub-array 1201 and 1202 having different array lengths. While the individual VCSEL devices are spaced at a regular array pitch in this example, other spacing options would work equally well. In FIG. 12b, the sub-arrays 1203, 1204, 1205 and 1206 are two dimensional arrays having different number of VCSEL devices in each group. The VCSEL array chip includes a plurality of bonding pads 1208 that connect to individual groups using a metal track 1207 (only one set labeled for clarity), or wire bonds, or configured to conform to surface mounting on a submount including a thermal submount, a PCB or other common platform.

It should be understood that the examples shown here are only illustrative and variations in array dimension, sizes, shapes, pitches (uniform or random) would work equally well. Each group of VCSEL devices may be activated independent of any other group, or they may be operated in pre-determined combinations, in pre-determined time-sequences, may be programmed remotely and/or dynamically, to configure sources to generate different structured illumination patterns. Other combinations and ways of operating that may occur to those skilled in the art, still fall within the broad framework of this description and are not precluded.

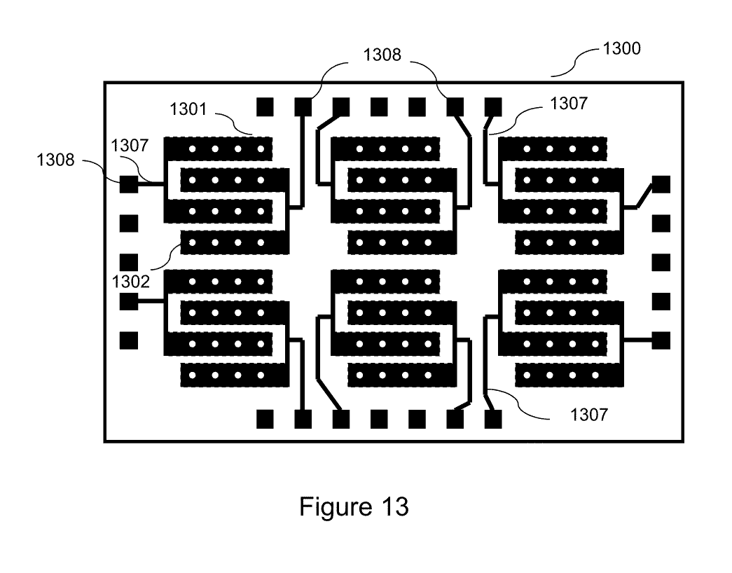

In another variation shown in FIG. 13, a VCSEL chip 1300 includes different groups of linear arrays 1301 and 1302 that are interleaved. The VCSEL chip has a plurality of bonding pads 1308 (only a few labeled for clarity) around the periphery of the chip. More specifically, several VCSEL devices (represented as 4 white dots in each group) are electrically connected as groups. Each group includes two linear sub-arrays (1301) connected in parallel to a common bonding pad 1308 via a metal track 1307 or a wire bond (not shown). A second identical group 1302 connected to a common bonding pad 1308 is interleaved between the two branches of the first group 1301. Each group may be operated independently, or in pre-determined combinations to generate a desired structured illumination pattern. While this example shows identical group of linear branching arrays, other types of arrays may be used within the purview of this description.

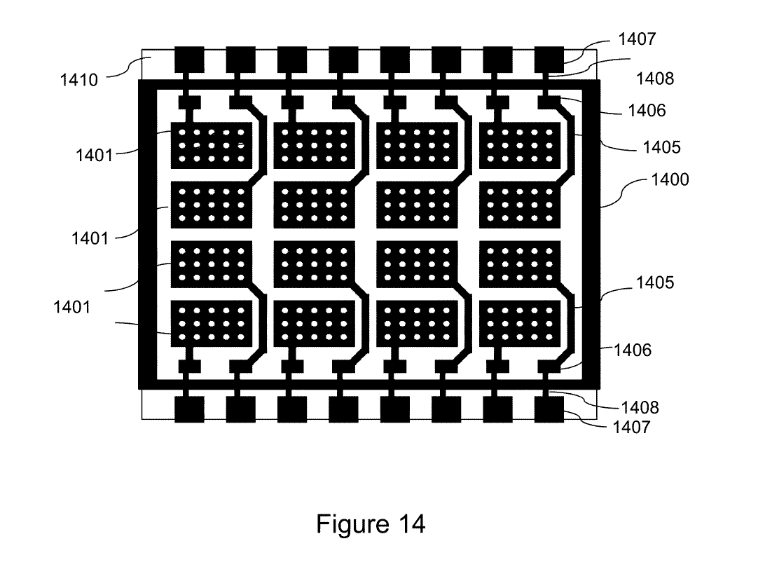

In yet another variation shown in FIG. 14, individual group or a sub-array of VCSEL devices is arranged in a 2-D array (array of arrays). In the example shown in FIG. 14, a VCSEL chip 1400 includes identical 2-D sub-arrays 1401 (only a few labeled for clarity) of VCSEL devices (represented as white dots) arranged in a two dimensional array. VCSEL devices in individual sub-array are electrically connected together to a common bonding pad 1406 located on two edges of the chip, using a metal track 1405 (or a wire bonding). A common second electrical contact of each sub-array may be located on the other side (not shown here). Each sub-array is electrically connected to be operated in individually addressable mode. A common bottom contact (not shown) of each sub-array is bonded to one or more bonding pad of a submount 1410 including a thermal submount. The submount includes an additional plurality of individual bonding pads 1407 (only a few labeled for clarity) located at opposite edges of the submount. A top contact of each sub-array is wire bonded (1408) to a respective bonding pad on the submount, to apply drive signal to each sub-array, preferably in a pre-determined sequence depending upon a desired structured illumination pattern to be generated. It can be well appreciated that individual VCSEL devices may be arranged in different ways to generate different structured illumination patterns.

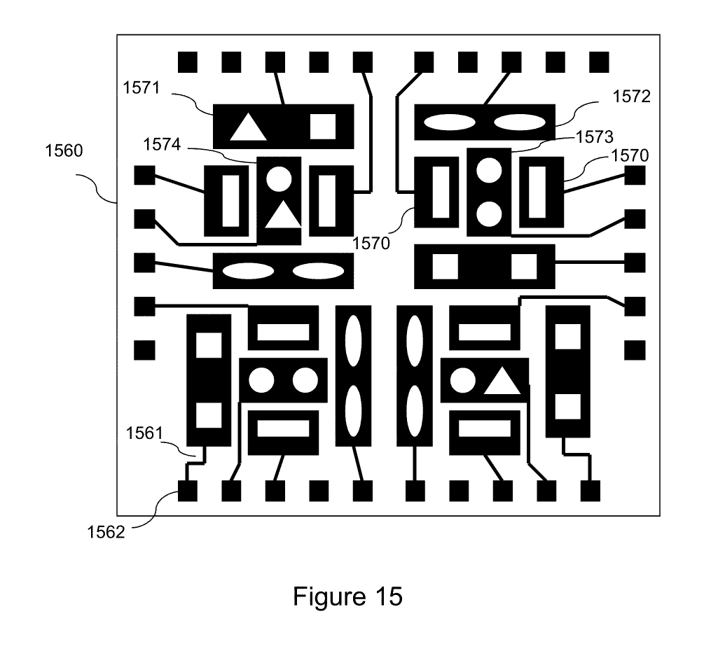

In another aspect of the invention, VCSEL devices having differently shaped emission profile may also be electrically configured in a pre-determined fashion such that individual VCSEL devices may be operated independently as individually addressable devices, or several VCSEL devices in an array may be connected in small groups, clusters or sub-arrays (hereinafter to be referred as groups in general for the ease of description) that are independently addressable. FIG. 15 illustrates some examples where VCSEL arrays generating structured illumination pattern having differently shaped emission profiles (illustrated in FIG. 10) are electrically connected to operate in different modes.

More specifically, FIG. 15 shows a planar view of a VCSEL array where VCSEL devices having differently shaped emission profiles are arranged as individually addressable VCSEL devices (1570) or pre-determined groups (1571, 1572, 1573 and 1574) that are individually addressable. Each group may include VCSEL devices having substantially similarly shaped emission profile (1572, 1573) or differently shaped emission profiles (1571, 1574). Each group is connected using a track 1561 (only one labeled) to a separate bonding pad 1562 (only one labeled) at the periphery of the chip 1560. Emission profiles of individual VCSEL devices in each group, array sizes in each group, arrangement of groups, number of groups on a chip, etc. shown in this example are merely illustrative and should not be construed as limiting. The shapes, grouping and locations are configured based on the optimum structured image of the system design. Such array structure can be mixed with standard circular arrays as well. VCSEL devices having differently shaped emission profile may be configured in pre-determined combinations to overlap and create emission beams having customized shapes.

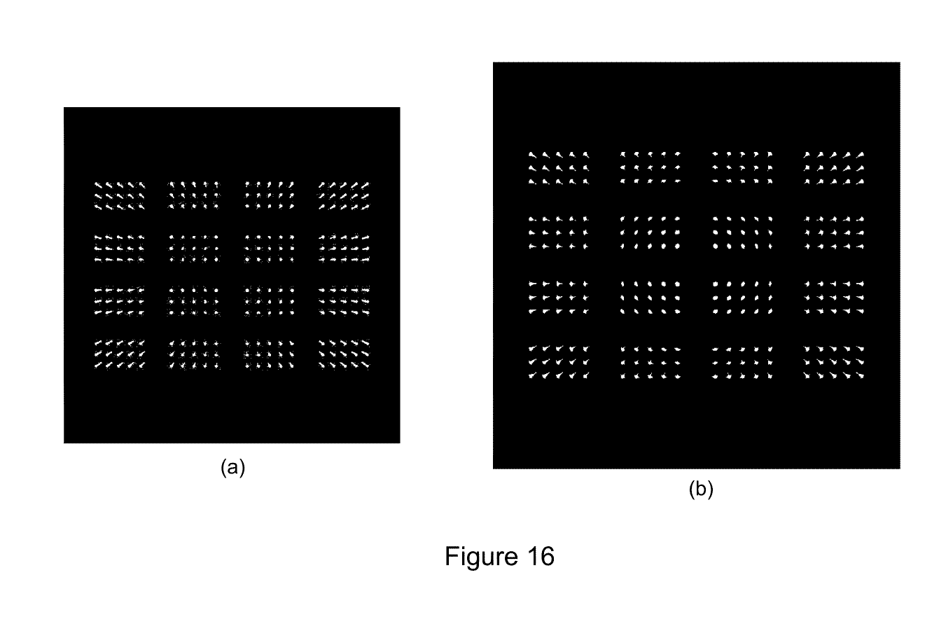

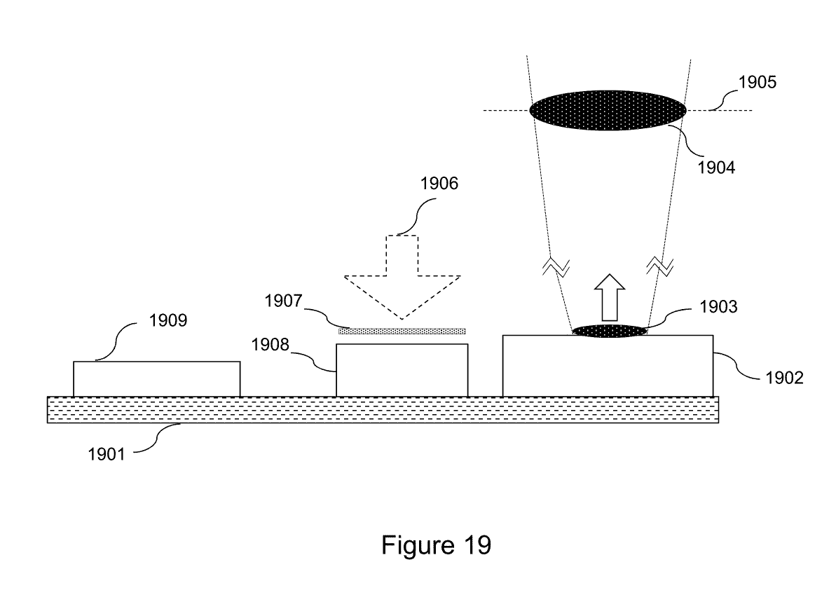

Structured illumination patterns projected using a densely (ultra-densely) packed VCESL array is shown in FIG. 16. More specifically, FIGS. 16a and 16b show photographs of a structured illumination pattern projected at two different distances from a structured light source comprising a VCSEL array similar to the one shown in FIG. 14. The structured light source to create the illumination pattern shown here comprise 240 VCSEL devices in a 1.02×0.684 mm². This particular photograph is taken when all the sub-array groups are operated together to emit 1.2W power (each VCSEL emitting about 5 mW). Projection optics is an aspheric lens having a focal length of 3.1 mm, and the two projection distances are 0.1 m and 5 m, respectively. The emission patterns in both the images are very clear and well separated from each other, and replicate each other perfectly at both the distances. Furthermore, the image at the longer distance (FIG. 19b) is distinctly larger and of same quality and resolution as the image at the shorter distance (FIG. 19a).

Imaging System using High Resolution Structured Light Source:

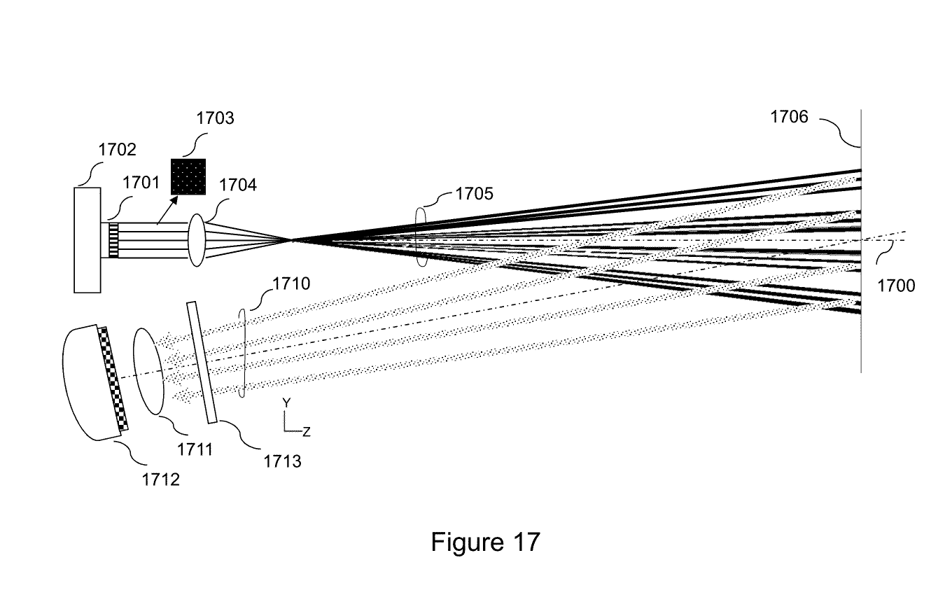

High resolution structured light source is applied in 3-D imaging systems including those that are used for gesture recognition. FIG. 17 shows a schematic representation of a gesture recognition system. A light source 1701 to illuminate an object, comprise a structured light source mounted on a thermal submount or a PCB having that is equipped with a heat dissipation mechanism. The source generates a structured illumination pattern 1703 in front of a projection system 1704 which projects an enlarged replica of the source illumination pattern collectively shown as 1705 on to an object located at an object plane 1706. Light reflected from the object plane collectively shown as 1710 is collected by an imaging lens 1711 on to a light sensing device 1712 placed at a pre-determined angle relative to the projection axis 1700.

The lens and sensor may be a camera (analog or digital), or lens and a detector array, a charge coupled detector (CCD), or any other imaging device known in the art. Since VCSEL emission spectrum is in a very narrow band of wavelengths, a narrow band filter 1713 may optionally be placed before the light sensing device to filter background noise and enhance system sensitivity significantly. The image received at the light sensing device is analyzed by correlating it with the projected structured illumination pattern and the sensor position to determine gesture properties including lateral position, depth and movement etc. of any moving objects in the illuminated region.

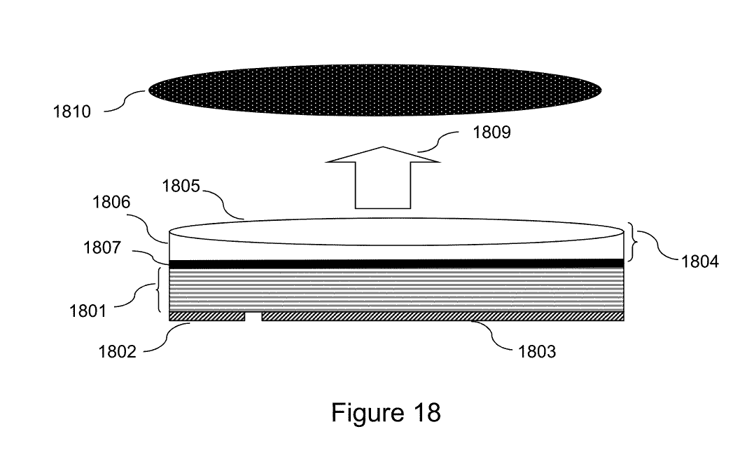

In one aspect of the invention, a very compact structured light source module is configured by integrating the light projection system on to the VCSEL array structured light source. An exemplary configuration is shown schematically in a cross section view in FIG. 18. More specifically, a structured light source including a VCSEL array collectively shown as 1801 is configured to have both electrical contacts 1802 and 1803 co-located on the bottom surface (in the perspective of this drawing) to facilitate direct surface mounting of the light source on to a submount including a thermal submount or a PCB (not shown). Additionally, electrical drive current to operate the light source may be provided through electrical pads on the submount. A projection system 1804 comprises projection optics such as a lens 1805 as shown in this example, bonded to a transparent substrate 1806. The thickness of the transparent substrate is determined according to the properties of the projection optics such that the structured illumination pattern may be imaged at a pre-determined fixed distance from the light source. The projection system is aligned with the structured light source and bonded in place using a transparent bonding material 1807. The structured illumination pattern 1809 is emitted through the projection system and an enlarged image of the structured illumination pattern is projected at a pre-determined fixed distance.

A compact structured light source, and in particular the compact structured light projection system described in reference with FIG. 18 is particularly attractive for integration with other electronic components on a submount including a thermal submount or a PCB to construct very compact high resolution imaging systems that are portable and are produced at a very low cost. In one exemplary embodiment of the invention shown in FIG. 19, a compact high resolution imaging system suitable for 3-D imaging or a gesture recognition application is provided. More specifically, an imaging system in this example is assembled on a printed circuit board (PCB) 1901, preferably one provided with a heat dissipation device/mechanism, for example a heat sink.

The structured light source comprises a VCSEL array chip mounted on a thermal submount for example, similar to the one shown in FIG. 14. In a preferred best practice mode, a VCSEL array chip is made compatible with surface mounting option of bonding it to the submount including a thermal submount or to a PCB. Furthermore, the thermal submount is made compatible with surface mounting option, some examples of which are described in the U.S. patent application Ser. No. 13/337,098 by Seurin et al. filed on Dec. 24, 2011, and is incorporated by reference, in this application. In a preferred configuration, a projection system is included with the structured light source as was described with reference to FIG. 18.

Referring now to FIG. 19, a compact projection system 1902 as described in reference to FIG. 18 is surface mounted on the PCB. An electronic integrated circuit (IC) device 1909 is also mounted on the same PCB so as to connect the driver electronics to the structured light source on board. A structured illumination pattern 1903 generated by the source. The projection system, integrated with the light source projects an enlarged replica 1904 of the structured illumination pattern to illuminate an object positioned at the object plane 1905. The light reflected from the object 1906 is received at the light sensing device 1908 (e.g. a camera, a photodetector or an array of photodetectors, a CCD, etc.). An optional narrow band filter 1907 is placed before the light sensing device to filter extraneous background light such that only the light at the emission wavelength of the source is sensed. The electronic IC device also includes operation and control electronics for the light sensing device as well as a processor to analyze the received signal to compute the 3-D image properties.

It should be noted that while the exemplary embodiments are described using commonly used top-emitting VCSEL devices and VCSEL arrays for the ease of description, same principles are equally applicable for bottom emitting VCSEL devices that exhibit better heat dissipation and therefore preferred for applications where high output power and high brightness devices are needed. Structured light source constructed according to this invention using densely and ultra-densely packed VCSEL arrays provide very high resolution structured illumination pattern thereby facilitating reconstruction of an object/scene with greater accuracy.

Since VCSELs can be constructed using different materials, different wavelength emission devices may be combined together in a modular fashion to create a multi-wavelength module. The surface mountable adaptation of VCSEL array integrated with projection systems facilitates integration of a structured light source with a wide range of fast electronic functions on a common platform such as a PCB. The structured light source configured for a wide range of individually addressable VCSEL devices or sub-arrays generate structured illumination patterns in more than one way which is extremely suitable for combining different imaging techniques on a single platform.

Various embodiments described in the previous sections provide a framework for practicing the invention to construct a wide range of structured light source and structured illumination patterns to illuminate an object or a scene for 3-D imaging applications. Variations and modifications of different embodiments that will be apparent to those skilled in the art are within the scope of the invention and are covered by appended claims.

What is claimed is:

1. A projection apparatus for generating high resolution structured illumination pattern comprising:
an optical source including one or more VCSEL arrays, wherein each VCSEL array including at least 5000, but no more than 500,000 VCSEL devices separated from adjacent VCSEL devices by a distance that is no more than 5 μm is configured to generate a desired one or more high resolution structured illumination patterns, and wherein each VCSEL array has an area proportional to the size of the VCSEL array; and
a projection device including at least one optical element to magnify and project the desired one or more illumination patterns on to an area distal to the optical source.

2. The projection apparatus as in claim 1, wherein the VCSEL devices comprise a planar device structure that includes a two-reflector, extended cavity three-reflector and external cavity three-reflector configurations that are wafer scale integrated using methods selected from a group consisting of monolithic integration on a common substrate, hybrid integration on a common substrate, assembled on a foreign substrate, and a combination thereof.

3. The projection apparatus as in claim 1 wherein each VCSEL array is identical to, or different from any other VCSEL array.

4. The projection apparatus as in claim 1, wherein each VCSEL device includes a current confining aperture, said current confining aperture including a region of a high electrical resistivity enclosing a region of high electrical conductivity, said current confining aperture generated by selectively modifying one or more pre-determined layers of the VCSEL devices.

5. The projection apparatus as in claim 4 wherein said current confining aperture is constructed using a method that is one selected from a group consisting of ion implantation, reactive ion etching, dopant diffusion, selective epitaxial regrowth, and a pre-determined combination thereof.

6. The projection apparatus as in claim 4, wherein said current confining apertures are of varying sizes, such that the structured illumination pattern has a desired variation in illumination intensity.

7. The projection apparatus as in claim 4, wherein said current confining apertures are of varying shapes that are regular geometric, irregular or random shapes, such that the structured illumination pattern having random shapes are generated by controllably superposing differently shaped emission from each VCSEL device in each VCSEL array.

8. The projection apparatus as in claim 1 further including a corresponding ones of optical mode apertures substantially aligned with the current confining apertures of the VCSEL devices, wherein said optical mode apertures are constructed in a metallization layer applied for electrical contacts to the VCSEL devices.

9. The projection apparatus as in claim 1, wherein the one or more VCSEL arrays are one selected from a group consisting of a regular array, a random array, and a combination thereof.

10. The projection apparatus as in claim 1, wherein the electrical contact to the emission surface of the VCSEL devices is provided using a transparent conducting layer that is one selected from a group consisting of a metal, a metal alloy, and a conducting metal oxide, such that the current flow is funneled through said transparent layer that forms an optical aperture for light emission and preventing the current to spread outside said optical aperture.

11. The projection apparatus as in claim 1 wherein, positioning of the adjacent VCSEL devices are selected to be at regular intervals or non-regular intervals.

12. The projection apparatus as in claim 1, wherein the VCSEL devices in the one or more VCSEL arrays is configured in a spatial arrangement that is one selected from a group consisting of a pre-determined group, cluster, sub-array, and a combination thereof.

13. The projection apparatus as in claim 13, wherein the VCSEL devices from each said group, cluster or sub-array are interleaved with VCSEL devices of at least one other said group, cluster or sub-array, so as to eliminate a self-contained group, cluster or sub-array in the one or more VCSEL arrays.

14. The projection apparatus as in claim 1 further including additional one or more optical components placed at a pre-determined distance from the optical source to further collimate radiation emitted from each one of the VCSEL devices or collective radiation emitted from the one or more VCSEL arrays, wherein the one or more optical components is one selected from the group consisting of microlens, array of microlens, lens and a pre-determined combination thereof.

15. The projection apparatus as in claim 1, wherein the VCSEL devices in the one or more VCSEL arrays is electrically connected to be operated in a mode that is one selected from a group consisting individually addressable, in a group, in a cluster, in a sub-array, a combination thereof, and a full array.

16. The projection apparatus as in claim 1, wherein the projection device may include one or more optical elements to achieve a desired magnification and distance of projection, such that the projected structured illumination pattern is of high resolution.

17. The projection apparatus as in claim 1 further including:
a programmable electronic driver to apply drive current to the VCSEL devices;
an imaging apparatus; and
an electronic controller, wherein the electronic controller drives the programmable electronic driver to operate the VCSEL devices in the one or more VCSEL arrays in a pre-determined timing sequence, and receives and processes light reflected from an object illuminated by the optical source in corresponding timing sequence, so as to generate a 3-D image of the object.

18. The projection apparatus as in claim 17, wherein the VCSEL devices in the one or more VCSEL arrays are individually addressable, addressable in pre-determined groups, cluster, sub-array or in pre-determined combinations thereof.

19. The projection apparatus as in claim 17 further including a narrow band pass optical filter having a center wavelength substantially matching the emission wavelength of the optical source, said optical filter is positioned in front of the imaging apparatus to allow reflected light only at source wavelength to be imaged while blocking light of other wavelengths.

20. The projection apparatus as in claim 17, wherein the imaging apparatus is one selected from a group consisting of a camera, a photo-detector, an array of photo-detectors, a charge coupled device, and a digital camera.
